(19) United States
(12) Patent Application Publication
(10) Pub. No.: US 2022/0131514 A1
(43) Pub. Date: Apr. 28, 2022

(54) METHOD FOR MANUFACTURING FILM BULK ACOUSTIC RESONANCE DEVICE HAVING SPECIFIC RESONANT FREQUENCY

(71) Applicant: Taiwan Carbon Nano Technology Corporation, Miaoli County (TW)

(72) Inventors: Tsung Fu YEN, Miaoli County (TW); Kuang-Jui Chang, Miaoli County (TW); Chiun-Shian Tsai, Miaoli County (TW); Ting-Chuan Lee, Miaoli County (TW); Chiun-Rung Tsai, Miaoli County (TW)

(73) Assignee: Taiwan Carbon Nano Technology Corporation

(21) Appl. No.: 17/506,940

(22) Filed: Oct. 21, 2021

(30) Foreign Application Priority Data
Oct. 22, 2020 (TW) 109136754

(51) Int. Cl. H03H 3/04; H03H 9/02; H03H 9/13; H03H 9/17

(52) U.S. Cl. CPC H03H 3/04; H03H 9/02031; H03H 2003/021; H03H 9/173; H03H 9/176; H03H 9/13

(57) ABSTRACT

A method for manufacturing a film bulk acoustic resonance device is disclosed. The proposed method, wherein the device has a specific resonant frequency, includes: providing an upper electrode; providing a lower electrode; configuring a first piezoelectric material layer between the upper electrode and the lower electrode; configuring a resonant frequency determining metal layer on the upper electrode, wherein the resonant frequency determining metal layer has a thickness; causing a resonant frequency of the film bulk acoustic resonance device and the thickness to form a curve; and when the thickness on the curve changes linearly, causing the resonant frequency to change non-linearly.

### CROSS-REFERENCE TO RELATED APPLICATION

The application claims the benefit of Taiwan Patent Application No. 109136754, filed on Oct. 22, 2020, at the Taiwan Intellectual Property Office, the disclosures of which are incorporated herein in their entirety by reference.

### TECHNICAL FIELD

The present disclosure is related to a semiconductor technique applied to a MEMS. Particularly, the present disclosure is applied to a MEMS used in a sensor and an energy-related device.

### BACKGROUND

The existing sensor technologies include pure mechanical sensors, CMOS sensors, MEMS sensors etc. However, the sensitivities of the above-mentioned sensors cannot fulfill requirements for detection of VOC gases of human beings such as via a portable device, e.g., a mobile phone. But, a film bulk acoustic resonance (FBAR) device having PZT can do this.

How to improve the existing FBAR technologies to let them have a better efficiency and/or a simpler structure, or a lower manufacturing cost is worthy of further research and improvement.

Keeping the drawbacks of the prior art in mind, and through the use of robust and persistent experiments and research, the applicant has finally conceived of a method for manufacturing a film bulk acoustic resonance device having a specific resonant frequency.

### SUMMARY

It is an objective of the present invention to provide a method for manufacturing a film bulk acoustic resonance device having a specific resonant frequency, comprising: providing an upper electrode; providing a lower electrode; configuring a first piezoelectric material layer between the upper electrode and the lower electrode; and configuring a resonant frequency determining metal layer on the upper electrode, wherein the resonant frequency determining metal layer has a thickness, and a curve relationship is formed between the specific resonant frequency and the thickness, wherein the specific resonant frequency changes non-linearly when the thickness changes linearly. FBAR devices respectively having resonant frequency determining metal layers with various thicknesses and manufactured via that method will respectively generate various resonant frequencies. Multiple FBAR devices having resonant frequency determining metal layers with various thicknesses can be used to simultaneously detect various VOC gases via multi-frequency control, and the same wafer can include a plurality of FBAR devices respectively having resonant frequency determining metal layers with various thicknesses to decrease the manufacturing costs.

In accordance with the first aspect of the present invention, a method for manufacturing a film bulk acoustic resonance device having a specific resonant frequency comprises: providing an upper electrode; providing a lower electrode; configuring a first piezoelectric material layer between the upper electrode and the lower electrode; configuring a resonant frequency determining metal layer on the upper electrode, wherein the resonant frequency determining metal layer has a thickness, and there is a curve relationship between the specific resonant frequency and the thickness, wherein when the thickness is located in a first range, the curve relationship is defined by a first curve segment, when the thickness is located in a second range, the curve is defined by a second curve segment, and a first slope of the first curve segment is larger than a second slope of the second curve segment; and depending on a specific thickness of the resonant frequency determining metal layer which corresponds to the specific resonant frequency, selecting the specific thickness to manufacture the film bulk acoustic resonance device.

In accordance with the second aspect of the present disclosure, a method for manufacturing a film bulk acoustic resonance device having a specific resonant frequency comprises: providing an upper electrode; providing a lower electrode; configuring a first piezoelectric material layer between the upper electrode and the lower electrode; and configuring a resonant frequency determining metal layer on the upper electrode, wherein the resonant frequency determining metal layer has a thickness, and a curve relationship is formed between the specific resonant frequency and the thickness, wherein the specific resonant frequency changes non-linearly when the thickness changes linearly.

### BRIEF DESCRIPTION OF THE DRAWINGS

Other objectives, advantages and efficacies of the present disclosure will be described in detail below taken from the preferred embodiments with reference to the accompanying drawings.

FIG. 1 shows a cross-section diagram of a FBAR device according to the preferred embodiment of the present disclosure.

FIG. 2 shows a wave diagram of a thickness of Au of a resonant frequency determining metal layer of a FBAR device versus a resonant frequency of the FBAR device according to the preferred embodiment of the present disclosure.

### DETAILED DESCRIPTION

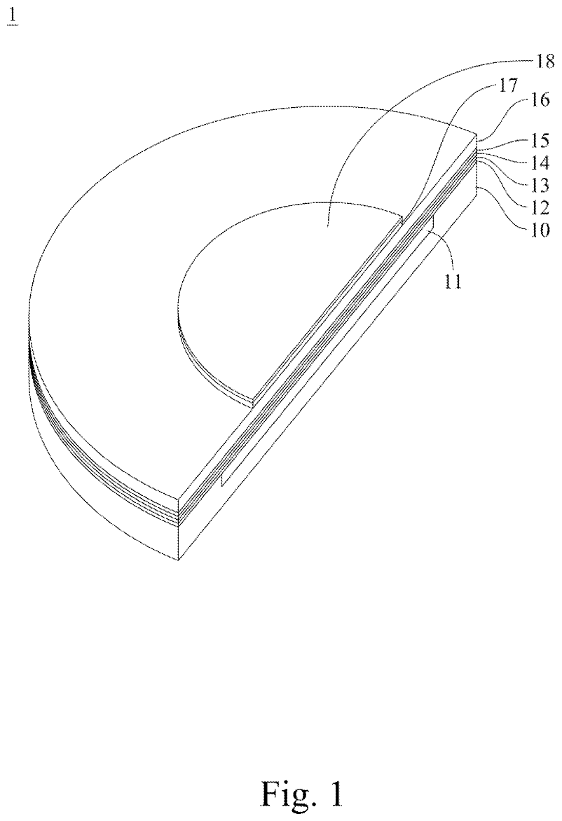

FIG. 1 is a cross-section diagram of a FBAR device according to the preferred embodiment of the present disclosure. In FIG. 1, a FBAR device 1 includes a substrate 10, a first insulating layer 12, a second insulating layer 13, a second piezoelectric material layer 14, a lower electrode 15, a first piezoelectric material layer (it is a piezoelectric material film) 16, an upper electrode 17 and a resonant frequency determining metal layer 18, wherein the first insulating layer 12 is configured on the substrate 10, the second insulating layer 13 is configured on the first insulating layer 12, the second piezoelectric material layer 14 is configured on the second insulating layer 13, the lower electrode 15 is configured on the second piezoelectric material layer 14, the first piezoelectric material layer 16 is configured on the lower electrode 15, the upper electrode 17 is configured on the first piezoelectric material layer 16, the resonant frequency determining metal layer 18 is configured on the upper electrode 17 and connected to a sensing material, and the sensing material is used to sense a resonant frequency of the FBAR device 1. In addition, there is an air gap 11 between the first insulating layer 12 and the substrate 10, and the air gap is vacuumized to exhibit a vacuum state.

As shown in FIG. 1, the substrate 10 includes a silicon (Si), the first insulating layer 12 includes a silicon nitride (SiN), the second insulating layer 13 includes a silicon dioxide (SiO2), the upper electrode 17 and the lower electrode 15 include Mo, the first piezoelectric material layer 16 and the second piezoelectric material layer 14 include aluminum nitride (AlN) or lead zirconium titanate (PZT), and the resonant frequency determining metal layer 18 includes Au.

In FIG. 1, a thickness of the resonant frequency determining metal layer 18 has a minimum of 0.05 μm, and the thickness has a maximum of 0.15 μm. For example, the thickness can be 0.05 μm (the first preferred embodiment), 0.1 μm (the second preferred embodiment), or 0.15 μm (the third preferred embodiment). A depth of the air gap 11 is 3 μm, thicknesses of the first insulating layer 12, the second insulating layer 13, the second piezoelectric material layer 14, the upper electrode 17 and the lower electrode 15 are all 0.2 μm, and a thickness of the first piezoelectric material layer 16 is 1 μm.

As shown in FIG. 1, the substrate 10, the first insulating layer 12, the second insulating layer 13, the second piezoelectric material layer 14, the lower electrode 15 and the first piezoelectric material layer 16 form a first cylinder, a first diameter of the first cylinder is, e.g., 200 μm, the air gap 11 form a second cylinder, a second diameter of the second cylinder is, e.g., 140 μm, the resonant frequency determining metal layer 18 and the upper electrode 17 form a third cylinder, and a third diameter of the third cylinder is, e.g., 100 μm.

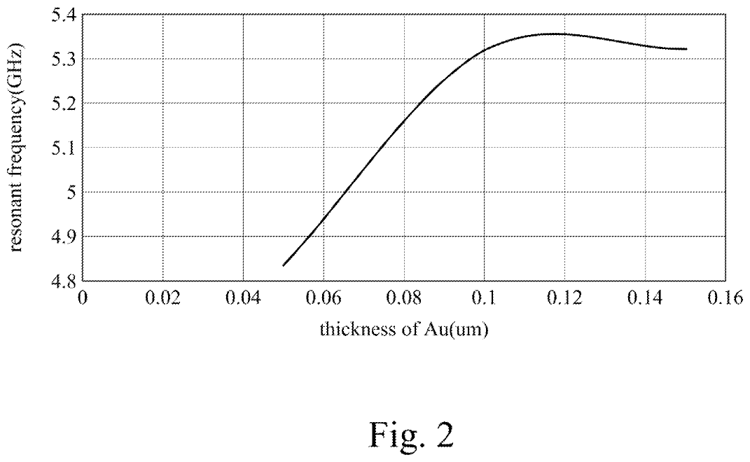

FIG. 2 is a wave diagram of a thickness of Au of a resonant frequency determining metal layer of a FBAR device versus a resonant frequency of the FBAR device according to the preferred embodiment of the present disclosure.

As shown in FIG. 2, when the resonant frequency determining metal layer 18 includes Au, and the thickness of Au increases from 0.1 μm to 0.15 μm, a first increased difference value of a resonant frequency of the FBAR 1 is about 21 KHz, and when the thickness of the Au of the resonant frequency determining metal layer 18 increases from 0.05 μm to 0.1 μm, a second increased difference value of the resonant frequency of the FBAR 1 is about 0.48 GHz. That is to say, it can be seen in FIG. 2, when the thickness of Au of the resonant frequency determining metal layer 18 is engaged in a linear change (e.g., the thickness of the Au of the resonant frequency determining metal layer 18 increases from 0.1 μm to 0.15 μm, or increases from 0.05 μm to 0.1 μm), the resonant frequency of the FBAR 1 presents a non-linear change (e.g., when the thickness of the Au of the resonant frequency determining metal layer 18 increases from 0.1 μm to 0.15 μm, the first increased difference value of the resonant frequency of the FBAR 1 is about 21 KHz, or when the thickness of the Au of the resonant frequency determining metal layer 18 increases from 0.05 μm to 0.1 μm, the second increased difference value of the resonant frequency of the FBAR 1 is about 0.48 GHz).

A method for manufacturing a film bulk acoustic resonance device 1 having a specific resonant frequency is proposed according to the fourth preferred embodiment of the present disclosure, and the method comprises: providing an upper electrode 17; providing a lower electrode 15; configuring a first piezoelectric material layer 16 between the upper electrode 17 and the lower electrode 15; and configuring a resonant frequency determining metal layer 18 on the upper electrode 17, wherein the resonant frequency determining metal layer 18 has a thickness, and a curve relationship is formed between the specific resonant frequency and the thickness, wherein the specific resonant frequency changes non-linearly when the thickness changes linearly.

The above-mentioned method proposed according to the fourth preferred embodiment of the present disclosure further includes: causing a first slope of a first curve segment defining the curve relationship being larger than a second slope of a second curve segment defining the curve relationship, wherein when the thickness is located in a first range, the curve is defined by the first curve segment, and when the thickness is located in a second range, the curve is defined by the second curve segment; and depending on a specific thickness of the resonant frequency determining metal layer 18 which corresponds to the specific resonant frequency, selecting the specific thickness to manufacture the film bulk acoustic resonance device 1.

A method for manufacturing a film bulk acoustic resonance device 1 having a specific resonant frequency is proposed according to the fifth preferred embodiment of the present disclosure, and the method comprises: providing an upper electrode 17; providing a lower electrode 15; configuring a first piezoelectric material layer 16 between the upper electrode 17 and the lower electrode 15 to form a core structure (15+16+17) of the film bulk acoustic resonance device 1; configuring a resonant frequency determining metal layer 18 on the upper electrode 17, wherein the resonant frequency determining metal layer 18 has a thickness, and there is a curve relationship between the specific resonant frequency and the thickness, wherein when the thickness is located in a first range, the curve relationship is defined by a first curve segment, when the thickness is located in a second range, the curve is defined by a second curve segment, and a first slope of the first curve segment is larger than a second slope of the second curve segment; and depending on a specific thickness of the resonant frequency determining metal layer 18 which corresponds to the specific resonant frequency, selecting the specific thickness to manufacture the film bulk acoustic resonance device 1.

When FBAR devices proposed according to the present disclosure are manufactured, the same wafer can include a plurality of FBAR devices respectively having resonant frequency determining metal layers with various thicknesses to decrease the manufacturing costs. For example, ten thousand dies having a thickness of a metal layer of 0.05 μm of the resonant frequency determining metal layer of the FBAR devices, ten thousand such dies having a thickness of a metal layer of 0.1 μm and ten thousand such dies having a thickness of a metal layer of 0.15 μm. Except for the various thicknesses of the resonant frequency determining metal layers, all the remaining structures of these thirty thousand dies are the same. Thus, except for the manufacturing process of the resonant frequency determining metal layer, all the remaining manufacturing processes of them are the same, and they can be manufactured by the same manufacturing process at the same time. And, when the resonant frequency determining metal layers are manufactured, there can be three manufacturing processes respectively adjusted for manufacturing three different thicknesses of the resonant frequency determining metal layers, but these metal layers are still manufactured on the same wafer at the same time. Therefore, their manufacturing costs are relatively lower than those of the above-mentioned dies respectively manufactured on three different wafers with three different thicknesses.

In conclusion, the present disclosure provides a method for manufacturing a film bulk acoustic resonance device having a specific resonant frequency, comprising: providing an upper electrode; providing a lower electrode; configuring a first piezoelectric material layer between the upper electrode and the lower electrode; and configuring a resonant frequency determining metal layer on the upper electrode, wherein the resonant frequency determining metal layer has a thickness, and a curve relationship is formed between the specific resonant frequency and the thickness, wherein the specific resonant frequency changes non-linearly when the thickness changes linearly. FBAR devices respectively having resonant frequency determining metal layers with various thicknesses and manufactured via that method will respectively generate various resonant frequencies. Multiple FBAR devices having resonant frequency determining metal layers with various thicknesses can be used to simultaneously detect various VOC gases via multi-frequency control, and the same wafer can include a plurality of FBAR devices respectively having resonant frequency determining metal layers with various thicknesses to decrease the manufacturing costs, which is both non-obvious and novel.

While the invention has been described in terms of what is presently considered to be the most practical and preferred embodiments, it is to be understood that the invention need not be limited to the disclosed embodiments. Therefore, it is intended to cover various modifications and similar configurations included within the spirit and scope of the appended claims, which are to be accorded with the broadest interpretation so as to encompass all such modifications and similar structures.

We claim:

1. A method for manufacturing a film bulk acoustic resonance device having a specific resonant frequency, comprising:
providing an upper electrode;
providing a lower electrode;
configuring a first piezoelectric material layer between the upper electrode and the lower electrode;
configuring a resonant frequency determining metal layer on the upper electrode, wherein the resonant frequency determining metal layer has a thickness, and there is a curve relationship between the specific resonant frequency and the thickness, wherein when the thickness is located in a first range, the curve relationship is defined by a first curve segment, when the thickness is located in a second range, the curve is defined by a second curve segment, and a first slope of the first curve segment is larger than a second slope of the second curve segment; and
depending on a specific thickness of the resonant frequency determining metal layer which corresponds to the specific resonant frequency, selecting the specific thickness to manufacture the film bulk acoustic resonance device.

2. The method according to claim 1, wherein the thickness has a minimum of 0.05 μm, the thickness has a maximum of 0.15 μm, the film bulk acoustic resonance device further comprises a substrate, a first insulating layer, a second insulating layer and a second piezoelectric material layer, the first insulating layer is configured on the substrate, the second insulating layer is configured on the first insulating layer, the second piezoelectric material layer is configured on the second insulating layer, the lower electrode is configured on the second piezoelectric material layer, there is an air gap between the first insulating layer and the substrate, and the air gap is vacuumized to exhibit a vacuum state.

3. The method according to claim 2, wherein the substrate includes a silicon, the first insulating layer includes a silicon nitride (SiN), the second insulating layer includes a silicon dioxide (SiO2), the upper electrode and the lower electrode include Mo, the first piezoelectric material layer and the second piezoelectric material layer include aluminum nitride (AlN) or lead zirconium titanate (PZT), and the resonant frequency determining metal layer includes Au.

4. A method for manufacturing a film bulk acoustic resonance device having a specific resonant frequency, comprising:
providing an upper electrode;
providing a lower electrode;
configuring a first piezoelectric material layer between the upper electrode and the lower electrode; and
configuring a resonant frequency determining metal layer on the upper electrode, wherein the resonant frequency determining metal layer has a thickness, and a curve relationship is formed between the specific resonant frequency and the thickness, wherein the specific resonant frequency changes non-linearly when the thickness changes linearly.

5. The method according to claim 4, wherein the film bulk acoustic resonance device further comprises a substrate, a first insulating layer, a second insulating layer and a second piezoelectric material layer, the first insulating layer is configured on the substrate, the second insulating layer is configured on the first insulating layer, the second piezoelectric material layer is configured on the second insulating layer, the lower electrode is configured on the second piezoelectric material layer, there is an air gap between the first insulating layer and the substrate, and the air gap is vacuumized.

6. The method according to claim 5, wherein the substrate includes a silicon, the first insulating layer includes a silicon nitride (SiN), the second insulating layer includes a silicon dioxide (SiO2), the upper electrode and the lower electrode include Mo, the first piezoelectric material layer and the second piezoelectric material layer include aluminum nitride (AlN) or lead zirconium titanate (PZT), and the resonant frequency determining metal layer includes Au.

7. The method according to claim 5, wherein the thickness has a minimum of 0.05 μm, the thickness has a maximum of 0.15 μm, a depth of the air gap is 3 μm, thicknesses of the first insulating layer, the second insulating layer, the second piezoelectric material layer, the upper electrode and the lower electrode are all 0.2 μm, and a thickness of the first piezoelectric material layer is 1 μm.

8. The method according to claim 7, wherein the substrate, the first insulating layer, the second insulating layer, the second piezoelectric material layer, the lower electrode and the first piezoelectric material layer form a first cylinder, a first diameter of the first cylinder is 200 μm, the air gap form a second cylinder, a second diameter of the second cylinder is 140 μm, the resonant frequency determining metal layer and the upper electrode form a third cylinder, and a third diameter of the third cylinder is 100 μm.

9. The method according to claim 7, wherein when the thickness of the resonant frequency determining metal layer increases from 0.1 μm to 0.15 μm, a first increased difference value of the specific resonant frequency is 21 KHz, and when the thickness of the resonant frequency determining metal layer increases from 0.05 μm to 0.1 μm, a second increased difference value of the specific resonant frequency is 0.48 GHz, the resonant frequency determining metal layer connects to a sensing material, and the sensing material senses the specific resonant frequency.

10. The method according to claim 7, further comprising:
causing a first slope of a first curve segment defining the curve relationship being larger than a second slope of a second curve segment defining the curve relationship, wherein when the thickness is located in a first range, the curve is defined by the first curve segment, and when the thickness is located in a second range, the curve is defined by the second curve segment; and
depending on a specific thickness of the resonant frequency determining metal layer which corresponds to the specific resonant frequency, selecting the specific thickness to manufacture the film bulk acoustic resonance device.
